(19) United States
(12) Patent Application Publication
(10) Pub. No.: US 2013/0240252 A1
(43) Pub. Date: Sep. 19, 2013

(54) 3D-SHAPED COMPONENT WITH A CIRCUIT TRACE PATTERN AND METHOD FOR MAKING THE SAME

(71) Applicant: TAIWAN GREEN POINT ENTERPRISES CO.,LTD, Taichung City (TW)

(72) Inventors: Yen-Chou CHEN, Taichung City (TW); Cheng-Yeh HSIAO, Taichung City (TW); Wen-Pao YANG, Taichung City (TW)

(73) Assignee: TAIWAN GREEN POINT ENTERPRISES CO., LTD, Taichung City (TW)

(21) Appl. No.: 13/710,846

(22) Filed: Dec. 11, 2012

Related U.S. Application Data
(60) Provisional application No. 61/612,589, filed on Mar. 19, 2012.

(51) Int. Cl. H05K 1/03

(52) U.S. Cl. CPC H05K 1/0313
USPC 174/255; 427/99.2

(57) ABSTRACT

A 3D-shaped component includes a 3D-shaped plastic film having a surface, and a circuit trace pattern that is disposed at the surface of the 3D-shaped plastic film, that is embedded in the 3D-shaped plastic film, and that is made from a cured conductive ink.

CROSS-REFERENCE TO RELATED APPLICATION

This application claims priority of U.S. Patent Provisional Application No. 61/612589, filed on Mar. 19, 2012.

### BACKGROUND OF THE INVENTION

1. Field of the Invention

The invention relates to a 3D-shaped component with a circuit trace pattern and a method for making the same, more particularly to a 3D-shaped component having a 3D-shaped plastic film and a circuit trace pattern embedded in the 3D-shaped plastic film.

2. Description of the Related Art

Conventional touch sensors having a circuit trace pattern can be formed by coating an indium-tin-oxide (ITO) layer on a plastic substrate, followed by photolithography of the ITO layer. However, since the ITO layer is very brittle and cannot be bent, it is not possible to form ITO trace elements on a flat substrate and then bend the ITO trace elements and the substrate to form a desired three dimensional-shaped (3D-shaped) component with curved ITO trace elements. In addition, the ITO layer is normally formed using sputtering techniques, which is under a temperature that is too high for most plastic substrates. Conventional touch sensors can also be made from a flexible printed circuit board. However, the flexible printed circuit board is expensive, and assembling the flexible printed circuit board with a plastic substrate increases the overall thickness of the 3D-shaped component. Neither the ITO layer on a substrate nor the flexible printed circuit board is suitable for use in making a 3D-shaped component with curved circuit trace elements.

U.S. Patent Application Publication No. 2008/0074330 discloses an electronic apparatus with an antenna and an anti-jamming system. The electronic apparatus comprises a casing and the antenna. The antenna is composed of a patterned metal thin film and a carrier, and is provided for processing a wireless signal. Combination of the casing and the antenna is conducted by injection molding. When the electronic apparatus is a display device, the anti-jamming system can modulate a clock signal generated by the display device to prevent the multiplication of the clock signal from interfering with signals within an operating band of the antenna.

U.S. Pat. No. 7,977,953 discloses an in-mold molding touch module including a plastic film, a touch circuit and a molding rind. The plastic film includes an inner surface and an outer surface for handling and touching. At least one region of the inner surface and a corresponding region of the outer surface cooperatively define a touch area. The touch circuit is arranged on the inner surface in the touch area. The molding rind is integrated on the inner surface by an in-mold injection mode to contain the touch circuit for forming a one-piece body.

People's Republic of China Patent Publication No. CN101587980 discloses a method for forming an antenna on a shell by inject ion-molding techniques. The method includes the steps of: coating a conductive ink on a plastic flint to form an antenna thereon; pressing and cutting an assembly of the plastic film and the antenna to form a feature unit; placing the feature unit in an injection molding machine; and injection molding a plastic material over the feature unit so as to form a shell directly on the feature unit.

### SUMMARY OF THE INVENTION

An object of the present invention is to provide a 3D-shaped component with a circuit trace pattern and a method for making the same that is simple and cost effective.

According to one aspect of the present invention, there is provided a 3D-shaped component with a circuit trace pattern. The 3D-shaped component comprises: a 3D-shaped plastic film having a surface; and a circuit trace pattern disposed at the surface of the 3D-shaped plastic film, embedded in the 3D-shaped plastic film, and made from a cured conductive ink.

According to another aspect of the pre sent invention, there is provided a method for making a 3D-shaped component having a circuit trace pattern. The method comprises: printing a circuit trace pattern of a curable conductive ink on a flat plastic film; curing the curable conductive ink on the flat plastic film; placing the flat plastic film together with the circuit trace pattern of the cured conductive ink in a mold cavity; softening the flat plastic film in the mold cavity by heating; and deforming the softened flat plastic film to the shape of the mold cavity by applying pressure to the softened flat plastic film so as to form a 3D-shaped plastic film with the circuit trace pattern.

### BRIEF DESCRIPTION OF THE DRAWINGS

In drawings which illustrate embodiments of the invention,

FIG. 1 is a schematic view of the first preferred embodiment of a 3D-shaped component with a circuit trace pattern according to the present invention;

FIGS. 2 to 5 are schematic views illustrating consecutive steps of a method of making the first preferred embodiment;

FIG. 6 is a schematic view of the second preferred embodiment of a 3D-shaped component with a circuit trace pattern according to the present invention;

FIG. 7 is a schematic view of the third preferred embodiment of a 3D-shaped component with a circuit trace pattern according to the present invention; and

FIG. 8 is a schematic view of the fourth preferred embodiment of a 3D-shaped component with a circuit trace pattern according to the present invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

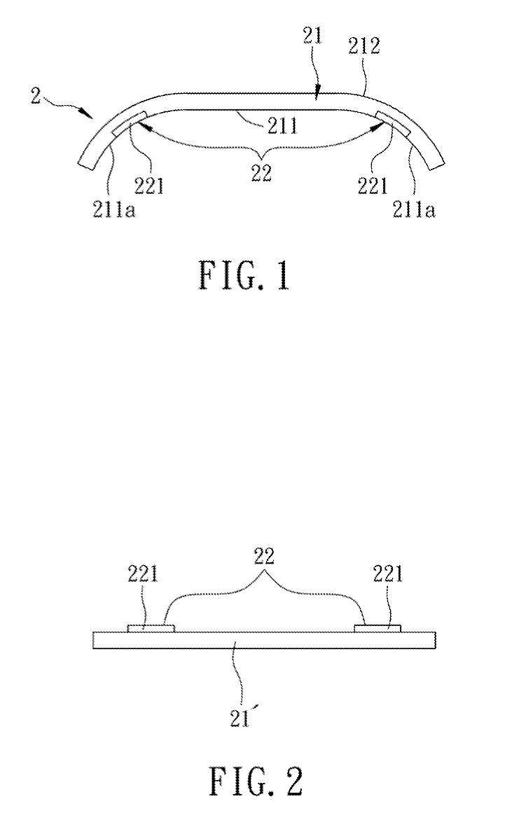

FIG. 1 illustrates the first preferred embodiment of a 3D-shaped component 2 for an electronic device, such as a mobile phone or a notebook computer, according to the present invention. The 3D-shaped component 2 can be a touch sensitive housing to provide touch function or can be a housing with a built-in antenna. The 3D-shaped component 2 includes: a 3D-shaped plastic film 21 having a first surface 211 and a second surface 212 opposite to the first surface 211; and a circuit trace pattern 22 that is disposed at the first surface 211 of the 3D-shaped plastic film 21, that is embedded in the 3D-shaped plastic film. 21, and that is made from a cured conductive ink.

The 3D-shaped plastic film 21 has a generally bow-shaped cross-section, The first surface 211 of the 3D-plastic film 21 has two opposite curved regions 211a. The circuit trace pattern 22 has a plurality of conductive trace elements 221 (only two trace elements 221 are shown for the sake of clarity) that are spaced apart from one another, that are disposed at the curved regions 211a of the first surface 211 of the 3D-shaped plastic film 21, respectively, and that are curved in shape.

Preferably, the 3D-shaped plastic film 21 is made from a material selected from polycarbonate (PC), polymethylmethacrylate (PMMA), and polyethylene terephthalate (PET).

The cured conductive ink is made from a curable conductive ink including an electrically conductive material and a UV or heat curable resin.

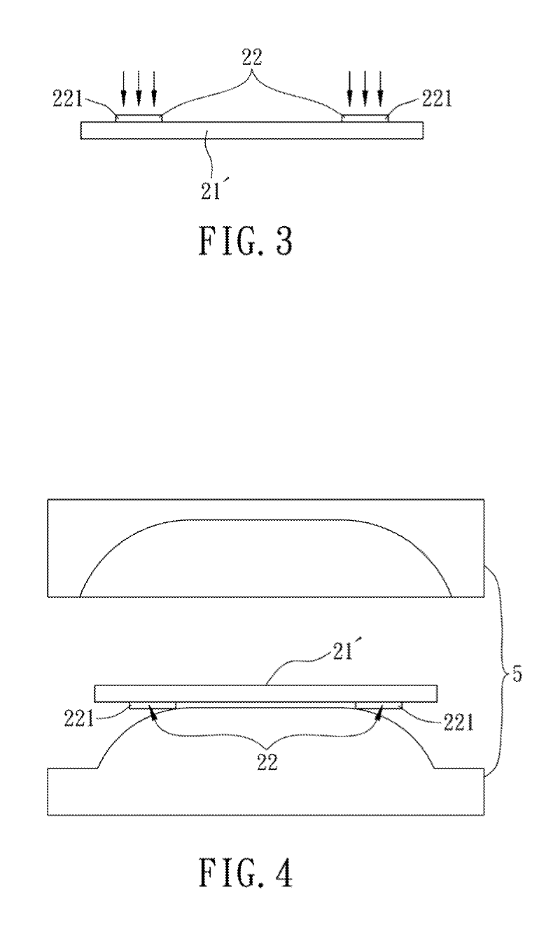

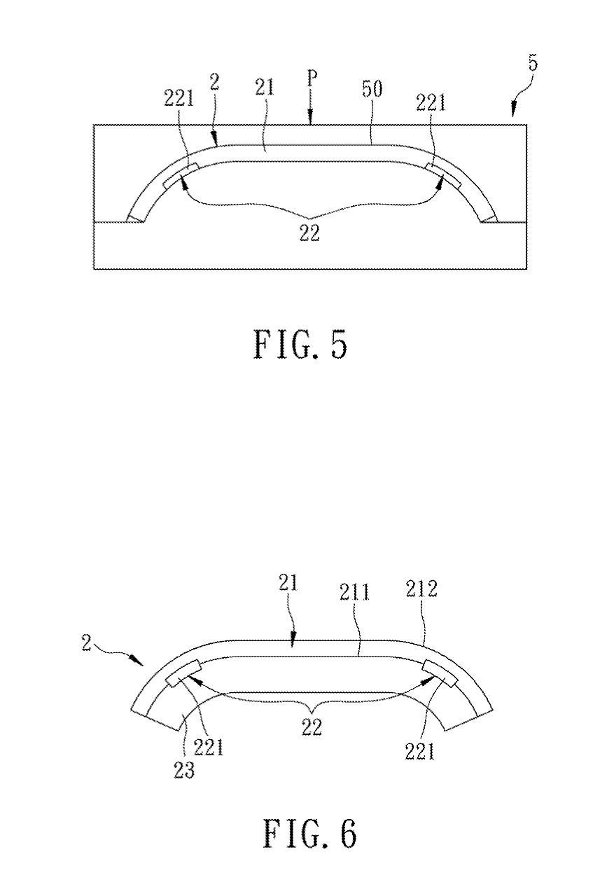

FIGS. 2 to 5 illustrate consecutive steps of a method of making the first preferred embodiment of the 3D-shaped component 2. The method includes: printing a circuit trace pattern 22 of a curable conductive ink on a peripheral region of a flat plastic film 21′ (see FIG. 2), the circuit trace pattern 22 having a plurality of conductive trace elements 221; curing the curable conductive ink on the flat plastic film 21′ using a UV light (see FIG. 3); placing the flat plastic film 21′ together with the circuit trace pattern 22 of the cured conductive ink in a mold cavity 50 in a mold 5 (see FIGS. 4 and 5); softening the flat plastic film 21′ in the mold cavity 50 by heating; deforming the softened flat plastic film 21′ to the shape of the mold cavity 50 by applying a pressure (P) to the softened flat plastic film 21′ so as to form the 3D-shaped component 2 including the 3D-shaped plastic film 21 and the circuit trace pattern 22 embedded in the 3D-shaped plastic film 21 (see FIG. 5); and cooling and removing the 3D-shaped component 2 from the mold 5 (see FIG. 1). During the deformation of the softened flat plastic film 21′ to the shape of the mold cavity 50, the peripheral region of the flat plastic film 21′ is curvedly deformed and the trace elements 221 of the circuit trace pattern 22 on the peripheral region are curvedly deformed as well. Therefore, the method of the present invention is capable of forming a circuit trace pattern on a curved surface to thereby facilitate the design of the electronic device and the utilization of space in the electronic device so as to reduce the dimensions of the electronic device.

The printing of the curable conductive ink on the flat plastic film 21′ to form the circuit trace pattern 22 can be conducted by screen printing, digital printing, pad printing, and offset printing. The curable ink employed can be transparent or have a silver color.

FIG. 6 illustrates the second preferred embodiment of the 3D-shaped component 2 according to the present invention. The second preferred embodiment differs from the first preferred embodiment in that the 3D-shaped component 2 further includes a 3D-shaped plastic feature part 23 that is molded over the first surface 211 of the 3D-shaped plastic film 21 and that covers at least a portion of the circuit trace pattern 22. The 3D-shaped plastic film 21 has a thickness less than that of the plastic feature part 23. Formation of the plastic feature part 23 on the 3D-shaped plastic film 21 is conducted by In-Mold Forming (IMF) techniques by placing the 3D-shaped plastic film 21 together with the circuit trace pattern 22 in an injection mold (not shown), followed by injecting a molten resin into the injection mold.

Preferably, the plastic feature part 23 is made from, a resin selected from polycarbonate (PC), acrylonitrile-butadiene-styrene (ABS), polymethyl-methacrylate (PMHA), and combinations thereof.

Preferably, formation of the plastic feature part 23 is conducted by IMF techniques using one of the aforementioned resins as the raw material under a mold temperature ranging from 80° C. to 90° C. When the mold temperature is less than 80° C., an undesired pattern shifting or deformation of the circuit trace pattern 22 by the flow of a molten resin occurs during injection of the molten resin in the injection mold, and when the mold temperature is greater than 90° C., the 3D-shaped plastic film 21 cannot withstand the mold temperature, which can cause an undesired film warping problem.

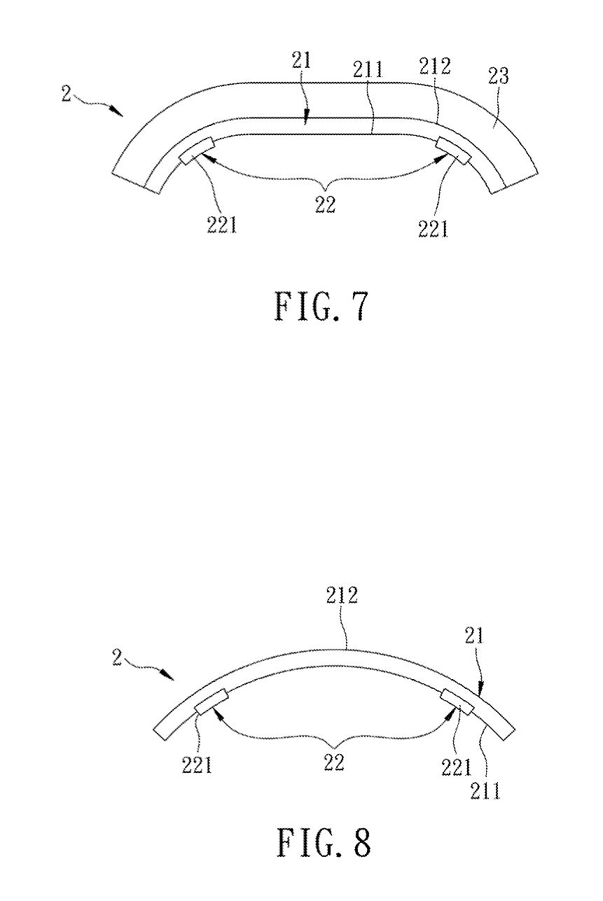

FIG. 7 illustrates the third preferred embodiment of the 3D-shaped component 2 according to the present invention. The third preferred embodiment differs from the second preferred embodiment in that the plastic feature part 23 is molded over the second surface 212 of the 3D-shaped plastic film 21.

FIG. 8 illustrates the fourth preferred embodiment of the 3D-shaped component 2 according to the present invention. The fourth preferred embodiment differs from the first preferred embodiment in that the 3D-shaped plastic film 21 is generally arcuate in shape.

By printing the curable conductive ink on the flat plastic film 21′ and softening and deforming the flat plastic film 21′ to the shape of the mold cavity SO according to the method of this invention, a 3D-shaped plastic film 21 with a circuit trace pattern 22 formed on a curved region 211a of the first surface 211 of the 3D-plastic film 21 can be formed and the aforesaid drawbacks associated with the use of the ITO layer on a substrate or the flexible printed circuit board for forming the 3D-shaped component can be overcome. In addition, since the circuit trace pattern 22 is embedded in the 3D-shaped plastic film 21 by virtue of the softening of the flat plastic film 21′ during the deforming process, the overall thickness of the 3D-shaped component 2 is reduced. Moreover, by controlling the mold temperature to foe within the range of from 80° C. to 90° C., the aforesaid pattern shifting or deformation of the circuit trace pattern 22 during injection of the molten resin for forming the plastic feature part 23 over the first surface 211 of the 3D-shaped plastic film 21 and the circuit trace pattern 22 can be alleviated.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A 3D-shaped component with, a circuit trace pattern, comprising:
a 3D-shaped plastic film, having a first surface; and
a circuit trace pattern, disposed at said first surface of said 3D-shaped plastic film, embedded in said 3D-shaped plastic film, and made from a cured conductive ink.

2. The 3D-shaped component of claim 1, wherein said 3D-shaped plastic film is made from a material selected from polycarbonate, polymethylmethacrylate, and polyethylene terephthalate.

3. The 3D-shaped component of claim 1, wherein said first surface of said 3D-plastic film has a curved region, at least a portion of said circuit trace pattern being disposed at. said curved region of said first surface of said 3D-shaped plastic film, and being curved in shape.

4. The 3D-shaped component of claim 1, further comprising a plastic feature part, said 3D-shaped plastic film further having a second surface opposite to said first surface and a thickness less than that of said plastic feature part, said plastic feature part being molded over said second surface of said 3D-shaped plastic film.

5. The 3D-shaped component of claim 1, further comprising a plastic feature part, said 3D-shaped plastic film, further having a thickness less than that of said plastic feature part, said plastic feature part being molded over said first surface of said 3D-shaped plastic film and covering at least a portion, of said circuit trace pattern.

6. A method for making a 3D-shaped component having a circuit trace pattern, the method comprising;
printing a circuit trace pattern of a curable conductive ink on a flat plastic film;
curing the curable conductive ink on the flat plastic film;
placing the flat plastic film together with the circuit trace pattern of the cured conductive ink in a mold cavity;
softening the flat plastic film in the mold cavity by heating; and
deforming the softened flat plastic film to the shape of the mold cavity by applying pressure to the softened flat plastic film so as to form a 3D-shaped plastic film with the circuit trace pattern.

7. The method of claim 6, wherein the 3D-shaped plastic film is made from a material selected from polycarbonate, polymethylmethacrylate, and polyethylene terephthalate.

8. The method of claim 7, further comprising forming a plastic feature part such that the plastic feature part is molded over a surface of the 3D-shaped plastic film, and covers at least a portion of the circuit trace pattern.

9. The method of claim 8, wherein the plastic feature part is made from a resin selected from polycarbonate, acrylonitrile-butadiene-styrene, polymethyl-methacrylate, and combinations thereof.

10. The method of claim 8, wherein formation of the plastic feature part is conducted by in-mold forming techniques under a mold temperature ranging from 80° C. to 90° C.
